(19) United States
(12) Patent Application Publication
(10) Pub. No.: US 2023/0014718 A1
(43) Pub. Date: Jan. 19, 2023

(54) SEMICONDUCTOR PACKAGE WITH TEMPERATURE SENSOR

(71) Applicant: TEXAS INSTRUMENTS INCORPORATED, Dallas, TX (US)

(72) Inventor: Enis Tuncer, Dallas, TX (US)

(21) Appl. No.: 17/376,150

(22) Filed: Jul. 14, 2021

(51) Int. Cl. H01L 23/34; H01L 23/31; H01L 23/495; H01L 21/48; H01L 21/56

(52) U.S. Cl. CPC H01L 23/34; H01L 23/3107; H01L 23/49513; H01L 23/4952; H01L 23/49555; H01L 23/49575; H01L 23/49589; H01L 21/4825; H01L 21/565

(57) ABSTRACT

A semiconductor package includes a first set of leads, a temperature sensor proximate the first set of leads, a second set of leads, a semiconductor die, a first electrical connection between the temperature sensor and the semiconductor die, a second electrical connection between the semiconductor die and the second set of leads, and mold compound at least partially covering the temperature sensor, the semiconductor die, the first set of leads and the second set of leads. The mold compound physically separates the semiconductor die from the temperature sensor and the first set of leads.

### TECHNICAL FIELD

This disclosure relates to semiconductor packages.

### BACKGROUND

Electronic package technology continues trends towards miniaturization, integration, and speed. Semiconductor packages provide support for a semiconductor die, such as an integrated circuit (IC) chip, and associated electrical connections, such as bond wires, provide protection from the environment, and enable surface-mounting of the die to and interconnection with an external component, such as a printed circuit board (PCB).

Leadframes are widely used in the electronics industry to house, mount, and interconnect a variety of semiconductor packages. A conventional leadframe is typically die-stamped from a sheet of flat stock metal and includes a plurality of metal leads temporarily held together in a planar arrangement about a central region during package manufacture by siderails forming a rectangular frame. A mounting pad or “die pad” for a semiconductor die is supported in the central region by “tie-bars” that attach to the frame. The leads extend from a first end integral with the frame to an opposite second end adjacent to, but spaced apart from, the die pad.

The die pad serves as a substrate providing a stable support for firmly positioning the semiconductor die within the semiconductor package during manufacturing, whereas the leads provide electrical connections from outside the package to the active surface of the semiconductor die. Gaps between the inner end of the leads and contact pads on the active surface of the semiconductor die are bridged by connectors, typically wire bonds—thin metal wires individually bonded to both the contact pads and the leads.

Semiconductor packages may further include a mold compound covering the pad, the semiconductor die, wire bonds, and portions of the leads. Such semiconductor packages may be created by a molding process, with a polymer compound, such as an epoxy formulation filled with inorganic granules, molded around an assembled semiconductor die and leadframe portions. In this process, a leadframe with the attached and bonded semiconductor die is placed in the cavity of a steel mold. Viscous mold compound is pressured into the cavity to fill the cavity and surround the semiconductor die and leadframe portions without voids. After polymerizing the compound, for example, by cooling to ambient temperature, the mold is opened, while the mold compound remains adhered to the molded parts.

Semiconductor dies are temperature-sensitive, and semiconductor packages utilize a variety of techniques to dissipate heat, such as exposed die pads and heat sinks. For semiconductor packages used for temperature sensing, a remote temperature sensor may connect to the package to separate the semiconductor die from a high-temperature environment. Alternatively, the package may include an optical temperature sensor to remotely monitor a temperature.

### BRIEF SUMMARY

Semiconductor packages disclosed herein include a temperature sensor and a semiconductor die configured to receive temperature signals from the temperature sensor. The temperature sensor is mounted proximate temperature sensing leads designed to be in direct contact with a component for temperature sensing, while the semiconductor die is separated from the temperature sensing leads and temperature sensor by mold compound, which functions as a thermal barrier. The semiconductor die includes electrical connections to the temperature sensor and other leads of the semiconductor die. In some examples, the temperature sensor includes a temperature sensitive capacitor. Disclosed examples may be suitable for high-temperature environments, eliminating the need for a semiconductor package with an optical temperature sensor or a separate remote temperature sensor.

In one example, a semiconductor package includes a first set of leads, a temperature sensor proximate the first set of leads, a second set of leads, a semiconductor die, a first electrical connection between the temperature sensor and the semiconductor die, a second electrical connection between the semiconductor die and the second set of leads, and mold compound at least partially covering the temperature sensor, the semiconductor die, the first set of leads and the second set of leads. The mold compound physically separates the semiconductor die from the temperature sensor and the first set of leads.

In another example, a method of forming a package includes mounting a temperature sensor to a first die pad proximate a first set of leads, mounting a semiconductor die to a second die pad, forming a first electrical connection between the temperature sensor and the semiconductor die, forming a second electrical connection between the semiconductor die and a second set of leads, and molding a dielectric mold compound to at least partially cover the temperature sensor, the semiconductor die, the first set of leads and the second set of leads such that the dielectric mold compound physically separates the semiconductor die from the temperature sensor and the first set of leads.

### BRIEF DESCRIPTION OF THE DRAWINGS

FIGS. 1A and 1B illustrate a semiconductor package including a temperature sensor and a semiconductor die separated from the temperature sensor by mold compound.

FIG. 2 illustrates a capacitive temperature sensor including a capacitor with interdigitated electrodes.

FIGS. 3A-3E illustrate conceptual process steps for manufacturing the semiconductor package of FIGS. 1A and 1B.

FIG. 4 is a flowchart of a method of manufacturing a semiconductor package including temperature sensor and a semiconductor die separated from the temperature sensor by mold compound, such as the semiconductor package of FIGS. 1A and 1B.

### DETAILED DESCRIPTION

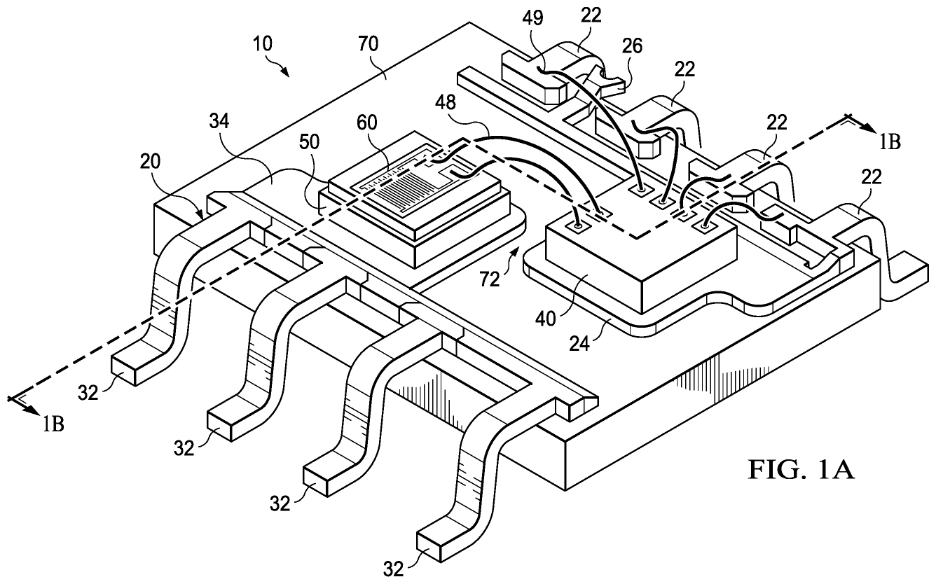

FIGS. 1A and 1B illustrate semiconductor package 10. In particular, FIG. 1A is a perspective view of semiconductor package 10 with a portion of mold compound 70 removed for illustrative purposes, whereas FIG. 1B is a conceptual cutaway side view of semiconductor package 10.

Semiconductor package 10 includes a semiconductor die 40 with an integrated circuit and a second semiconductor die 50 with a temperature sensor 60. Semiconductor die 40 is electrically connected to temperature sensor 60 with a set of wire bonds 48, but physically separated from temperature sensor 60 by mold compound 70, which functions as a thermal barrier.

Semiconductor package 10 further includes a leadframe 20. Leadframe 20 includes a first die pad 34 coupled to a first set of leads, temperature sensing leads 32, and a second die pad 24 adjacent to a second set of leads, die leads 22. In addition, a tie bar portion 26 extends to an external surface of mold compound 70. In the example of package 10, temperature sensing leads 32 are on a first side of the package, whereas die leads 22 are opposite the first side on a second side of the package. Such a configuration allows temperature sensing leads 32 to be placed in contact a heat source, while die leads 22 are electrically coupled to an external board, such as a PCB. For example, temperature sensing leads 32 may be thermally coupled to the heat source with a solder, while die leads 22 are electrically coupled to the external board with solder. In some examples, the heat source may be a component mounted to the PCB.

Semiconductor die 40 is mounted to die pad 24 by securing an inactive side of semiconductor die 40 to die pad 24 with a die attach adhesive, such as a die attach paste. Die pad 34 and temperature sensing leads 32 form a continuous electrical and thermal conductor. Die 50, including temperature sensor 60 on a semiconductor substrate, is mounted on die pad 34 by securing the semiconductor substrate with a die attach adhesive, such as a die attach paste, to facilitate conductive temperature sensing of leads 32 via die pad 34. Die attach pastes may include metallic fillers (such as silver particles) and provide better thermal conductivity between the die 50 and die pad 34 compared to die attach films.

Die pad 24 and die leads 22 are physically and electrically separated from die pad 34 and temperature sensing leads 32 by gap 72. Mold compound 70 fills gap 72 to thermally and electrically isolate semiconductor die 40 from die pad 34.

Wire bonds 48, 49 provide electrical connections between the components of package 10. Specifically, wire bonds 48 provide a first electrical connection between bond pads 42 of semiconductor die 40 and bond pads 62 of temperature sensor 60, whereas wire bonds 49 provide a second electrical connection between bond pads 42 of semiconductor die 40 and die leads 22. In the example of package 10, wire bonds 48 include ball bonds on bond pads 42 of semiconductor die 40 and stitch bonds on bond pads 62 of temperature sensor 60. Likewise, wire bonds 48 include ball bonds on bond pads 42 of semiconductor die 40 and stitch bonds on the lead attachment areas of die leads 22.

Temperature sensing leads 32 provide a direct thermal path for connection to an outside component, while die leads 22 provide electrical connections between semiconductor die 40 and external components, such as via a PCB. In the example of semiconductor package 10, exposed portions of leads 22, 32 are bent in a common direction outside mold compound 70 and shaped as cantilevered leads. In other examples, leads 22, 32 may have other configurations, including, but not limited to, a shape conforming to Small Outline No-Lead (SON) devices, such as Quad Flat No-Lead (QFN) devices. In one example, the individual temperature sensing leads 32 may be replaced with a single wider lead to increase the contact area with the heat source and improve thermal coupling between the die pad 34 and the heat source. Such a wider lead may extend the full width of temperature sensing leads 32, including the spaces between temperature sensing leads 32.

Semiconductor die 40 may include any combination of semiconductor elements such as transistors and integrated circuits. In various examples of this disclosure, semiconductor die 40 may be implemented using any semiconductor material employed in industry, such as a silicon, silicon germanium, gallium arsenide, gallium nitride (GaN), such as GaN-on-silicon or GaN-on-silicon carbide, or other semiconductor material. In addition, the techniques of this disclosure may be applied to semiconductor packages with any combination of active and passive components on a leadframe in addition to semiconductor die 40 and temperature sensor 60. In some examples, semiconductor die 40 is an integrated circuit including a controller configured to receive an analog input from temperature sensor 60 via wire bonds 48, the analog input representing a temperature of the temperature sensor 60, and output a digital signal representative of the temperature of the temperature sensor via die leads 22. Example digital signals may include any representation of temperature, such as, but not limited to, responding to an external request for a temperature reading, discrete temperatures on a continuous or periodic basis, outputting of an alarm if a sensed temperature is outside preprogrammed limits and/or control signals, such a signals to operate a cooling fan or shutdown a heat-generating device in response to a sensed temperature. In some examples, semiconductor die 40 may include a programmable controller operable to output any or all of such digital signals representative of the analog temperatures sensed by temperature sensor 60.

Leadframes, such as leadframe 20, including leads 22, 32 and die pads 24, 34, are formed on a single, thin sheet of metal as by stamping or etching. In various examples, the base metal of leadframe 20 may include copper, copper alloys, aluminum, aluminum alloys, iron-nickel alloys, or nickel-cobalt ferrous alloys. For many devices, parallel surfaces of the flat leadframe base metal are treated to create strong affinity for adhesion to plastic compound, especially mold compounds. As an example, the surfaces of metal leadframes may be oxidized to create a metal oxide layer, such as copper oxide. Other methods include plasma treatment of the surfaces, or deposition of thin layers of other metals on the base metal surface. In some examples, the planar base metal may be plated with a plated layer enabling metal-to-metal bonding and resistant to oxidation. In an example, the plated layer may include a layer of nickel plated on the base metal and a layer of palladium plated on the nickel layer. Some of such examples, a layer of gold may be plated on the palladium layer. As an example, for copper leadframes, plated layers of tin may be used, or a layer of nickel, about 0.5 to 2.0 μm thick in some examples, followed by a layer of palladium, about 0.01 to 0.1 μm thick in the same or different examples, optionally followed by an outermost layer of gold, about 0.003 to 0.009 μm thick in the same or different examples. Such base metal and plating combinations provide resistance to corrosion, such as oxidation, at exposed portions of leadframe 20 while facilitating wire bonds 49.

Multiple interconnected leadframes may be formed from a single sheet of a metal substrate, the interconnected leadframes referred to as a leadframe strip. Leadframes on the sheet can be arranged in rows and columns. Tie bars (not shown) interconnect leads and other elements of a leadframe to one another as well as to elements of adjacent leadframes in a leadframe strip. A siderail (not shown) may surround the array of leadframes to provide rigidity and support leadframe elements on the perimeter of the leadframe strip. The siderail may also include alignment features to aid in manufacturing.

Usually die mounting, die to lead attachment, such as wire bonding, and molding to cover at least part of the leadframe and dies take place while the leadframes are still integrally connected as a leadframe strip. After such processes are completed, the leadframes, and sometimes mold compound of a package, are severed (“singulated” or “diced”) with a cutting tool, such as a saw or laser. These singulation cuts separate the leadframe strip into separate semiconductor packages, each semiconductor package including a singulated leadframe, at least one die, electrical connections between the die and leadframe (such as gold or copper wire bonds) and the mold compound which covers at least part of these structures.

Tie bars and siderails may be removed during singulation of the packages formed with a single leadframe strip. The term leadframe of represents the portions of the leadframe strip remaining within a package after singulation. With respect to semiconductor package 10, leadframe 20 includes leads 22, 32, die pads 24, 34, and tie bar portion 26, although some of these elements are not interconnected following singulation of semiconductor package 10 into a discrete package.

Mold compound 70 forms an overmold covering semiconductor die 40, die 50 with temperature sensor 60, and partially covering leads 22, 32 and die pads 24, 34. In this manner, mold compound 70 provides a protective outer layer for the electric components of semiconductor package 10. While mold compound 70 covers the upper surfaces of semiconductor die 40, die 50 with temperature sensor 60, leads 22, 32, and die pads 24, 34, as best illustrated in FIG. 1B, this portion of mold compound 70 is not shown in FIG. 1A.

In the example, of semiconductor package 10, both die pads 24, 34 remain exposed on an outer surface of the package. In other examples, one or both of die pads 24, 34 may be covered by mold compound. For example, an exposed die pad 34 may be utilized to promote heat transfer between the die pad and the component being measured, whereas exposed die pad 24 may be used to dissipate heat from semiconductor die 40, using a heat sink, for example. Depending on the particular application, it may be best to cover die pad 24 to shield it from the heat source, and/or cover die pad 34 to prevent undesired heat transfer to the external environment.

In some examples, mold compound 70 includes a resin, such as an epoxy-based thermoset polymer. The resin of mold compound 70 may be filled or unfilled and include one or more of the following: resin, hardener, curing agent, fused silica, inorganic fillers, catalyst, flame retardants, stress modifiers, adhesion promoters, and other suitable components. Fillers, if any, may be selected to modify properties and characteristics of the resin base materials. Inert inorganic fillers may be selected to lower CTE, increase thermal conductivity, increase elastic modulus of the mold compound compared to the resin base. Particulate fillers may be selected to reduce strength characteristics such as tensile strength and flexural strength compared to the resin base materials.

Usually die mounting, die to lead attachment, such as wire bonding, and molding to cover at least part of leadframe 20 and dies 40, 50 take place while the leadframes are still integrally connected as a leadframe strip. After such processes are completed, the leadframes, and sometimes mold compound of a semiconductor package, are severed (“singulated” or “diced”) with a cutting tool, such as a saw or laser, within spaces separating the semiconductor dies from each other. These singulation cuts separate the leadframe strip into separate semiconductor packages, each semiconductor package including a singulated leadframe, at least one die, electrical connections between the die and leadframe (such a flip chip connection or wire bonds) and the mold compound which covers at least part of these structures.

Tie bars and siderails of a leadframe strip are removed or partially removed during singulation of the semiconductor packages formed with a single leadframe strip. The term leadframe represents the portions of the leadframe strip remaining within a semiconductor package after singulation. With respect to semiconductor package 10, leadframe 20 includes die leads 22 with die pad 24, temperature sensing leads 32 and die pad 34 forming the thermal path although some of these elements are not interconnected following singulation of semiconductor package 10 into a discrete semiconductor package.

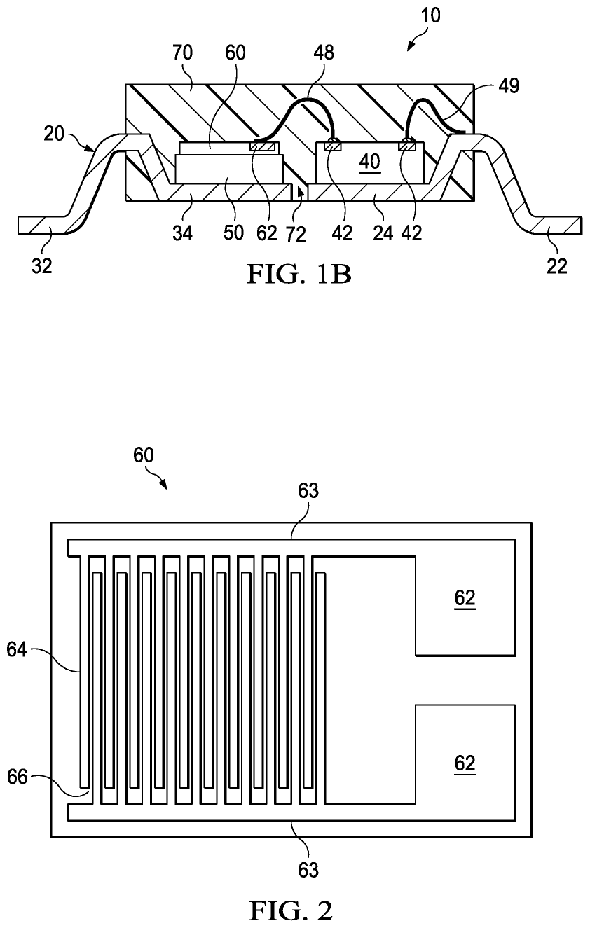

FIG. 2 illustrates temperature sensor 60. Temperature sensor 60 is a capacitive temperature sensor including a capacitor for capacitance measurement formed with interdigitated electrodes 64 separated by a dielectric material 66. Temperature sensor 60 includes two bond pads 62, each representing one terminal for the capacitor. An electrical trace 63 extends from each of bond pads 62 electrically connecting interdigitated electrodes 64 to bond pads 62. Interdigitated electrodes 64 extend from the electrical traces 63 in an alternating format. These conductive elements are formed in a common plane to support thin-film manufacturing. However, some elements, such as bond pads 62, may include additional layers as needed to facilitate wire bonding.

Dielectric material 66 is selected to provide a temperature-sensitive capacitance. For example, dielectric material 66 may be a ceramic material. The ceramic material may include aluminum nitride (AlN). AlN provides a temperature-dependent capacitance across a broad temperature range. For example, the dielectric permittivity (c) of AlN ranges from about 9.2 to 10.8 over a temperature range of 0 to 600 degrees Celsius. In an example of temperature sensor 60 utilizing AlN for dielectric material 66, the inventors found that the quality factor (Q) of the capacitor ranged from about 30 to about 3 over a temperature range of 0 to 600 degrees Celsius. Thus, the quality factor is detectable as an analog input representing a temperature of the temperature sensor by semiconductor die 40 (FIG. 1A)

AlN provides high thermal conductivity, which facilitates heat transfer from leads 32 via die pad 34. AlN also provides high electrical insulation capacity, low thermal expansion, and good metallization capacity. Other materials suitable for use as dielectric material 66 to provide a temperature-sensitive capacitance include Al₂O₃, TiO₂, and HfO₂.

The capacitor of temperature sensor 60 may be a thin film capacitor manufactured on a substrate, such a conductive, nonconductive or semiconductor substrate. The substrate, if any, should have a high thermal conductivity to facilitate heat transfer from leads 32 via die pad 34. In other examples, the conductive elements of the capacitor may be printed directly on the dielectric material 66 without a separate substrate.

Other configurations of temperature sensor 60 are also suitable for use in package 10. In an alternative example, a temperature sensor may include a thin film capacitor with at least two planar electrodes separated by a planar dielectric material. Like temperature sensor 60, such a thin film capacitor may be with or without a separate substrate, such as a semiconductor substrate. In yet other examples, the capacitor may be a fixed capacitor made out of two or more alternating layers of ceramic and metal. As with temperature sensor 60, dielectric material of any alternative capacitors should be selected to provide a temperature-sensitive capacitance.

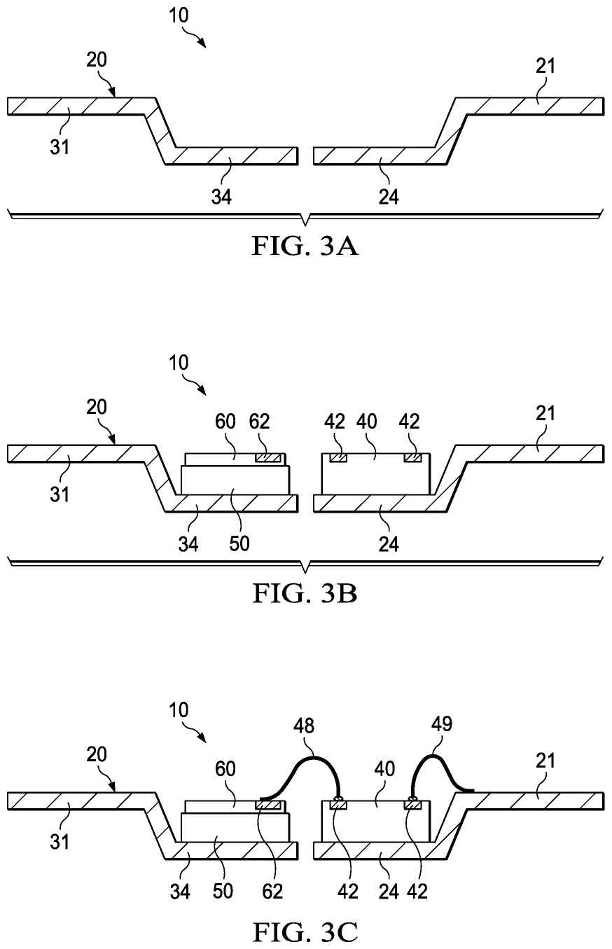

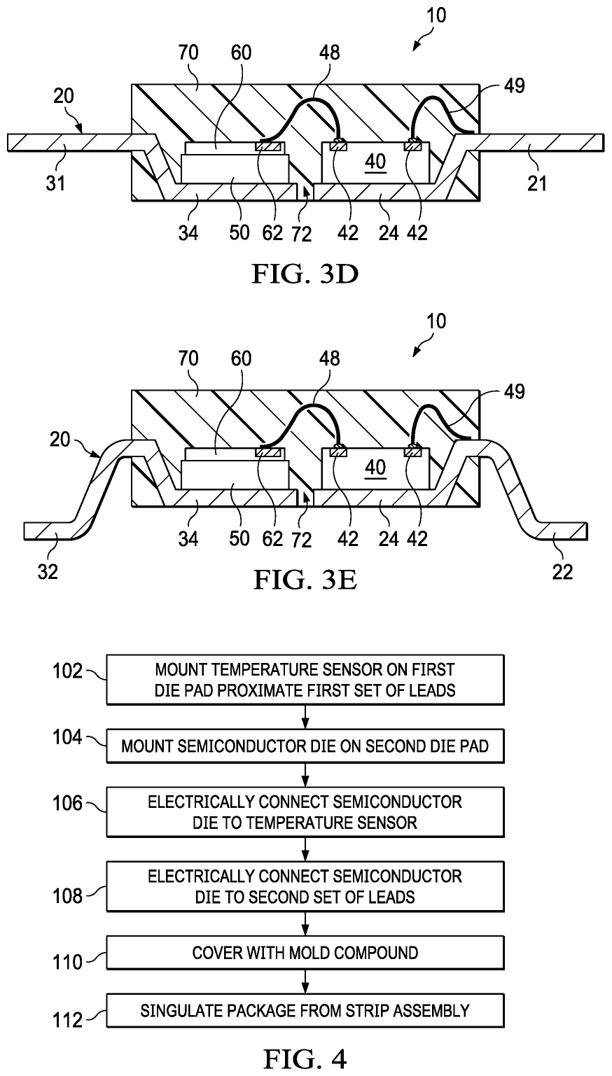

FIGS. 3A-3E are conceptual cutaway side views of process steps for manufacturing a semiconductor package including a temperature sensor and a semiconductor die separated from the temperature sensor by mold compound. The cutaway side views of FIGS. 3A-3E are from the same perspective as FIG. 1B. FIG. 4 is a flowchart of a method of manufacturing a semiconductor package including a temperature sensor and a semiconductor die separated from the temperature sensor by mold compound, such as semiconductor package 10. For clarity, the method of FIG. 4 is described with reference to semiconductor package 10 and FIGS. 3A-3E; however, the described techniques may be adapted to other semiconductor package designs and are not limited to the specific example of semiconductor package 10.

As shown in FIG. 3A, leadframe 20 includes die pad 24 coupled to lead end 21 and die pad 34 coupled to lead end 31. Other lead ends 21 are spaced from die pad 24 as best illustrated with respect to leads 22 in FIG. 1A. Die pads 24, 34 are offset from lead ends 21, 31, creating recessed mounting surfaces relative to leads ends 21, 31. In other examples, leadframe 20 may have a planar configuration. While not illustrated in FIG. 3A, lead ends 21 may be coupled to tie bars and/or siderails as part of a leadframe strip.

As shown in FIG. 3B, temperature sensor 60 is mounted on die pad 34 of leadframe 20. Specifically, the substrate of die 50 is bonded to die pad 34 (FIG. 4, step 102). Mounting temperature sensor 60 to die pad 34 may include applying a die attach paste to either the substrate of die 50 or the die pad 34 before placing die 50 in contact with die pad 34.

As also shown in FIG. 3B, semiconductor die 40 is mounted on die pad 24 of leadframe 20 with an inactive surface of semiconductor die 40 bonded to die pad 24 (FIG. 4, step 104). Mounting semiconductor die 40 to die pad 24 may include applying a die attach paste to either the inactive surface of semiconductor die 40 or die pad 24 before placing semiconductor die 40 in contact with die pad 24.

As shown in FIG. 3C, after semiconductor die 40 is bonded to pad 24 and die 50 including temperature sensor 60 is bonded to pad 34, a subset of bond pads 42 of semiconductor die 40 are electrically connected to bond pads 62 of temperature sensor 60 with wire bonds 48 (FIG. 4, step 106). Wire bonds 48 each include a metal wire extending from a respective bond pad 42 to a respective bond pad 62. Each of wire bonds 48 include a ball bond by a squashed ball attached the respective bond pad 42, and a stitch bond attached to the respective bond pad 62.

As also shown in FIG. 3C, after semiconductor die 40 is bonded to pad 24, a subset of bond pads 42 of semiconductor die 40 are electrically connected to lead stich areas corresponding to lead ends 21 of leadframe 20 with wire bonds 49 (FIG. 4, step 108). Wire bonds 49 each include a metal wire extending from a respective bond pad 42 to a respective lead stich area. Each of wire bonds 49 include a ball bond by a squashed ball attached the respective bond pad 42, and a stitch bond attached to the respective lead stich area. The metal wires of wire bonds 48, 49 are made of electrically conductive materials, such as copper, gold, or aluminum.

As shown in FIG. 3D, the assembly of FIG. 3C is molded to cover semiconductor die 40, die 50 with temperature sensor 60, and die pads 24, 34, and partially cover leads 22, 32 with mold compound 70, such as by placing the subassembly of FIG. 3D, in a mold cavity and transfer molding the subassembly (FIG. 4, step 110).

In some examples, semiconductor package 10 may be manufactured as part of an array of semiconductor packages on a common leadframe strip. In such examples, semiconductor die 40 is one of a plurality of semiconductor dies mounted on a plurality of leadframes in the leadframe strip, the plurality of leadframes including leadframe 20. Likewise, temperature sensor 60 is one of a plurality of temperature sensor 60 mounted on the plurality of leadframes in the leadframe strip. Following the mounting of the plurality of semiconductor dies 40 and temperature sensors 60, wire bonds 48, 49 are formed. Mold compound 70 is then applied to each of the semiconductor packages on the leadframe strip with a single molding operation. Following molding of mold compound 70, semiconductor package 10 may be singulated from the array of interconnected semiconductor packages of the common mold (FIG. 4, step 112). For example, singulation may include cutting the leadframe strip including leadframe 20 and mold compound 70 within spaces separating the plurality of semiconductor dies from each other with a saw or other cutting implement.

Following singulation to form discrete semiconductor packages 10, leads ends 21, 31 extend beyond mold compound 70. As shown in FIG. 3E, leads ends 21, 31 are bent in a common direction to form cantilevered leads 22, 32. Cantilevered leads 22, 32 suitable for surface mounting semiconductor package 10 to an external board, such as a PCB. Specifically, temperature sensing leads 32 may be thermally coupled to a heat source of the external component, while die leads 22 provide electrical connections to the external board. In some examples, lead bending and singulation may occur in a single operation.

Following singulation, semiconductor package 10 may be tested or placed into operation. For example, operation or testing of semiconductor package 10 may include receiving, with a controller of semiconductor die 40, an analog input representing the temperature of temperature sensor 60 from temperature sensor 60, and outputting, with the controller, digital signals representative of the temperature of temperature sensor 60 via one or more of die leads 22.

The specific techniques for semiconductor packages including a temperature sensor and a semiconductor die separated from the temperature sensor by mold compound, such as semiconductor package 10, are merely illustrative of the general inventive concepts included in this disclosure as defined by the following claims.

What is claimed is:

1. A semiconductor package comprising:
a first set of leads;
a temperature sensor proximate the first set of leads;
a second set of leads;
a semiconductor die;
a first electrical connection between the temperature sensor and the semiconductor die;
a second electrical connection between the semiconductor die and the second set of leads; and
mold compound at least partially covering the temperature sensor, the semiconductor die, the first set of leads and the second set of leads,
wherein the mold compound physically separates the semiconductor die from the temperature sensor and the first set of leads.

2. The semiconductor package of claim 1, wherein the temperature sensor includes a temperature-sensitive capacitor.

3. The semiconductor package of claim 2, wherein the temperature-sensitive capacitor includes interdigitated electrodes for capacitance measurement, the interdigitated electrodes separated by a dielectric material.

4. The semiconductor package of claim 2, wherein the temperature-sensitive capacitor is a thin-film capacitor.

5. The semiconductor package of claim 2, wherein the temperature-sensitive capacitor includes a ceramic dielectric material separating conductive elements of the temperature-sensitive capacitor.

6. The semiconductor package of claim 5, wherein the ceramic dielectric material includes aluminum nitride (AlN).

7. The semiconductor package of claim 2, wherein the temperature-sensitive capacitor includes a dielectric material including one or more of a group consisting of:
Al₂O₃;
TiO₂; and
HfO₂.

8. The semiconductor package of claim 1, further comprising:
a first die pad coupled to at least one of the first set of leads; and
a second die pad,
wherein the temperature sensor is mounted to the first die pad, and
wherein the semiconductor die is mounted to the second die pad.

9. The semiconductor package of claim 1,
wherein the first set of leads are on a first side of the semiconductor package, and
wherein the second set of leads are opposite the first side on a second side of the semiconductor package.

10. The semiconductor package of claim 1,
wherein the first electrical connection includes wire bonds extending between sensor bond pads of the temperature sensor and a first set of bond pads of the semiconductor die, and
wherein the second electrical connection includes wire bonds extending between a second set of bond pads of the semiconductor die and the second set of leads.

11. The semiconductor package of claim 1, wherein the semiconductor die is electrically isolated from first set of leads.

12. The semiconductor package of claim 1, wherein the first set of leads and the second set of leads extend beyond external surfaces of the mold compound.

13. The semiconductor package of claim 12, wherein exposed portions of the first set of leads and the second set of leads are bent in a common direction beyond the external surfaces of the mold compound.

14. The semiconductor package of claim 1, wherein the semiconductor die is an integrated circuit including a controller configured to receive an analog input from the temperature sensor, the analog input representing a temperature of the temperature sensor, and output a digital signal representative of the temperature of the temperature sensor via the second set of leads.

15. A method of forming a semiconductor package comprising:
mounting a temperature sensor to a first die pad proximate a first set of leads;
mounting a semiconductor die to a second die pad;
forming a first electrical connection between the temperature sensor and the semiconductor die;
forming a second electrical connection between the semiconductor die and a second set of leads; and
molding a dielectric mold compound to at least partially cover the temperature sensor, the semiconductor die, the first set of leads and the second set of leads such that the dielectric mold compound physically separates the semiconductor die from the temperature sensor and the first set of leads.

16. The method of claim 15, wherein the first die pad is coupled to at least one of the first set of leads.

17. The method of claim 15,
wherein mounting the temperature sensor to the first die pad includes securing the temperature sensor on the first die pad with a die attach adhesive, and
wherein the die attach adhesive includes metal particles.

18. The method of claim 15, wherein the temperature sensor includes a temperature-sensitive capacitor with interdigitated electrodes for capacitance measurement, the interdigitated electrodes separated by a dielectric material.

19. The method of claim 18, wherein the dielectric material includes aluminum nitride (AlN).

20. The method of claim 15,
wherein forming the first electrical connection between the temperature sensor and the semiconductor die includes forming a first set of one or more wire bonds between the semiconductor die and the temperature sensor, and
wherein forming the second electrical connection between the semiconductor die and the second set of leads includes forming a second set of one or more wire bonds between the semiconductor die and the second set of leads.

21. The method of claim 15, wherein the semiconductor die is an integrated circuit including a controller, the method further comprising:
receiving, with the controller, an analog input from the temperature sensor, the analog input representing a temperature of the temperature sensor; and
outputting, with the controller, a digital signal representative of the temperature of the temperature sensor via the second set of leads.
